(19) United States
(12) Patent Application Publication
(10) Pub. No.: US 2019/0215986 A1
(43) Pub. Date: Jul. 11, 2019

(54) WATER-COOLING RADIATOR ASSEMBLY

(71) Applicant: ASIA VITAL COMPONENTS CO., LTD., New Taipei City (TW)

(72) Inventor: Wen-Ji Lan, New Taipei City (TW)

(21) Appl. No.: 15/867,708

(22) Filed: Jan. 11, 2018

(51) Int. Cl. H05K 7/20; H01L 23/473

(52) U.S. Cl. CPC H05K 7/20254; H01L 23/473; H05K 7/20172; H05K 7/20272; H05K 7/20409

(57) ABSTRACT

A water-cooling radiator assembly includes a liquid-receiving plate unit and a first flow-disturbing unit. The liquid-receiving plate unit includes a first and a second liquid-receiving plate. The first liquid-receiving plate internally defines a first liquid chamber and has at least one liquid inlet provided thereon to communicate with the first liquid chamber, and a working liquid flows into the first liquid chamber via the at least one liquid inlet. The second liquid-receiving plate internally defines a second liquid chamber and has at least one liquid outlet provided thereon to communicate with the second liquid chamber. At least one communicating pipe is communicably connected to between the first and the second liquid chamber; and the first flow-disturbing unit is selectively arranged in one of the first and the second liquid chamber.

### FIELD OF THE INVENTION

The present invention relates to a water-cooling radiator assembly, and more particularly, to a water-cooling radiator assembly that provides good heat dissipation effect.

### BACKGROUND OF THE INVENTION

Many electronic elements in a computer will produce a large quantity of heat when the computer operates. Hence, a good heat dissipation system is a key factor that determines the effectiveness and reliability of a computer. In a computer, the workload of the central processing unit (CPU) and the graphic processing unit (GPU) is higher than any other heat-producing elements in the computer, and accordingly, solutions for dissipating heat produced by the CPU and the GPU are no doubt very important. Particularly, the currently available computer games all include highly exquisite images that require computer-aided design (CAD) software with increasingly enhanced functions to achieve. However, the operation of such CAD software will render the CPU and the GPU into a heavy workload state to produce a huge quantity of heat. Heat accumulated in the computer would result in lowered performance of the CPU and GPU, or, in some worse condition, even result in damages or largely shortened service life of the CPU and GPU.

Different water cooling systems are available in the market for lowering the working temperature of the heat-producing electronic elements. A conventional water cooling system generally includes a water-cooling radiator 1 fluid-communicably connected to a pump 1a and a water block 1b via two water pipes. The water block 1b is in contact with a heat-producing element, such as a CPU. The pump 1a drives a cooling liquid, i.e. a working fluid such as water, from the water block 1b to flow into the water-cooling radiator 1, so that heat absorbed and carried by the working fluid is transferred to and dissipated from the water-cooling radiator 1 into ambient air. The pump 1a drives the cooling liquid to continuously circulate between the water-cooling radiator 1 and the water block 1b to enable quick removal of heat from the heat-producing electronic element. FIG. 1 shows a conventional water-cooling radiator structure 1, which includes a plurality of radiating fins 11, a plurality of straight flat pipes 12, and two side water tanks 13. The radiating fins 11 are arranged between any two adjacent flat pipes 12 and the two side water tanks 13 are soldered to the radiating fins 11 and two opposite ends of the flat pipes 12, so that the two side water tanks 13, the radiating fins 11 and the straight flat pipes 12 together constitute the water-cooling radiator structure 1. A first one of the two side water tanks 13 is provided with a water inlet 131 and a water outlet 132, which are separately connected to the above-mentioned two water pipes (not shown).

The working fluid flowed into the first side water tank 13 via the water inlet 131 quickly and straightly flows through the straight flat pipes 12 to the second side water tank 13, and then quickly flows back to the first side water tank 13 via the straight flat pipes 12 and leaves the water-cooling radiator structure 1 via the water outlet 132. Therefore, the time period from the entering to the leaving of the heat-carrying working fluid into and from the water-cooling radiator structure 1 is very short and there is not sufficient time for the heated working fluid to exchange heat with the water-cooling radiator structure 1. As a result, the conventional water-cooling radiator structure 1 could not effectively remove the heat from the working fluid flowing therethrough and has the problem of poor heat dissipation efficiency. In addition, the conventional water-cooling radiator structure 1 is an integral structure, which is not adjustable or changeable according to the internal space of an electronic device that uses the water-cooling radiator structure 1. Therefore, to use the water-cooling radiator structure 1 inside an electronic device, the electronic device must have an independent internal space sufficient for installing the water-cooling radiator structure 1.

### SUMMARY OF THE INVENTION

A primary object of the present invention is to provide a water-cooling radiator assembly that has good heat removal performance.

Another object of the present invention is to provide a water-cooling radiator assembly that includes a liquid-receiving plate unit having a first and a second liquid-receiving plate. At least one of the two liquid-receiving plates is internally provided with a flow-disturbing unit for effectively disturbing a working liquid flowing through the liquid-receiving plate unit, so as to lower the flow speed and increase the flow time of the working liquid in the liquid-receiving plate while providing an internal structural support to the liquid-receiving plate and effectively upgrading the heat dissipation efficiency of the water-cooling radiator assembly.

A further object of the present invention is to provide a water-cooling radiator assembly that includes a plurality of liquid-receiving plates communicable with one another via a plurality of communicating pipes, and the number and positions of the liquid-receiving plates and of the communicating pipes are freely adjustable according to an inner space available in an electronic device, in which the water-cooling radiator assembly is to be mounted.

A still further object of the present invention is to provide a water-cooling radiator assembly that includes a plurality of liquid-receiving plates, and any one or all of the liquid-receiving plates can be made of a titanium material that has high metal strength, low weight and good heat transfer efficiency to effectively upgrade the heat dissipation efficiency and reduce the overall weight of the water-cooling radiator assembly.

To achieve the above and other objects, the water-cooling radiator assembly according to the present invention includes a liquid-receiving plate unit and a first flow-disturbing unit. The liquid-receiving plate unit includes a first and a second liquid-receiving plate. The first liquid-receiving plate internally defines a first liquid chamber and has at least one liquid inlet provided thereon to communicate with the first liquid chamber, and a working liquid flows into the first liquid chamber via the at least one liquid inlet. The second liquid-receiving plate internally defines a second liquid chamber and has at least one liquid outlet provided thereon to communicate with the second liquid chamber. At least one communicating pipe is communicably connected to between the first and the second liquid chamber; and the first flow-disturbing unit is selectively arranged in one of the first and the second liquid chamber. With these arrangements, it is able to lower the flow speed and increase the flow time of the working liquid in the first or the second liquid-receiving plate to enable upgraded heat dissipation performance of the water-cooling radiator assembly of the present invention.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is an assembled perspective view of a prior art water-cooling radiator structure;

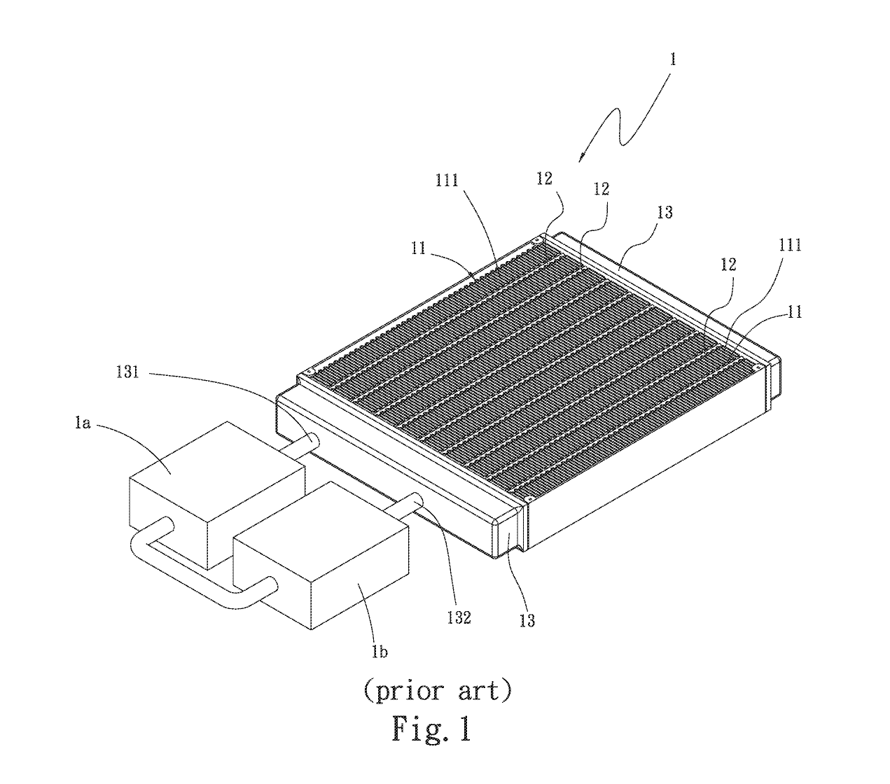

FIG. 2 is an assembled perspective view of a water-cooling radiator assembly according to a first embodiment of the present invention;

FIG. 2A is a sectional view of FIG. 2;

FIG. 3A is an exploded top perspective view of the water-cooling radiator assembly according to the first embodiment of the present invention;

FIG. 3B is an exploded bottom perspective view of the water-cooling radiator assembly according to the first embodiment of the present invention;

FIG. 3C is an enlarged view of the circled area 3C in FIGS. 3A and 4A;

FIG. 4A is an exploded perspective view of a water-cooling radiator assembly according to a second embodiment of the present invention;

FIG. 4B is an assembled sectional view of the water-cooling radiator assembly of FIG. 4A;

FIG. 5A is an exploded top perspective view of a water-cooling radiator assembly according to a third embodiment of the present invention;

FIG. 5B is an exploded bottom perspective view of the water-cooling radiator assembly according to the third embodiment of the present invention;

FIG. 5C is an enlarged view of the circled area 5C in FIG. 5A;

FIG. 6 is an assembled sectional view of the water-cooling radiator assembly of FIG. 5A;

FIG. 7 is an assembled perspective view of a water-cooling radiator assembly according to a fourth embodiment of the present invention; and

FIG. 8 is a partially exploded perspective view of a water-cooling radiator assembly according to a fifth embodiment of the present invention.

### DETAILED DESCRIPTION OF THE PREFERRED EMBODIMENTS

The present invention will now be described with some preferred embodiments thereof and by referring to the accompanying drawings. For the purpose of easy to understand, elements that are the same in the preferred embodiments are denoted by the same reference numerals.

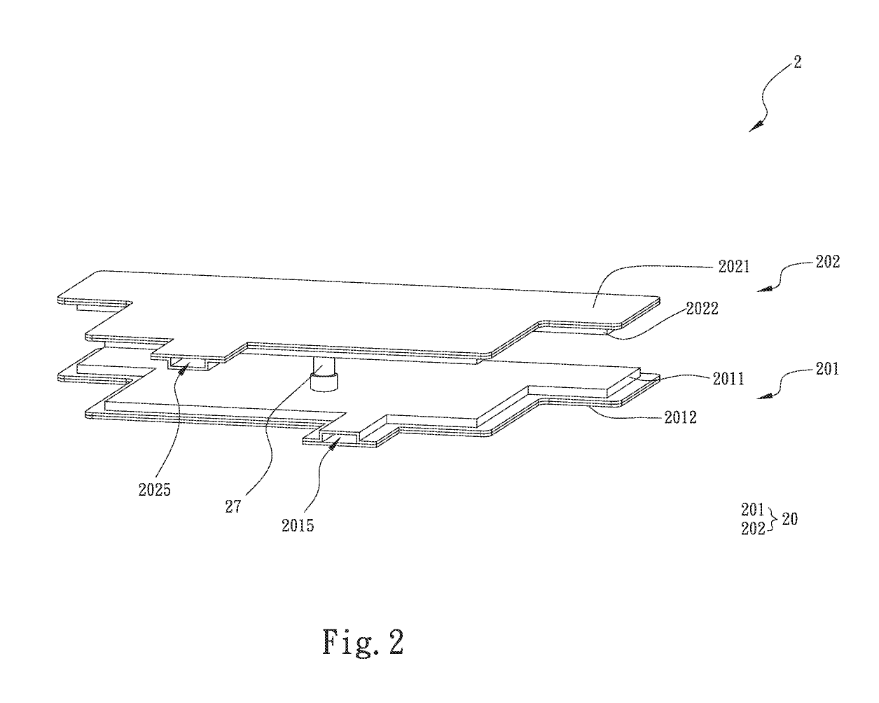

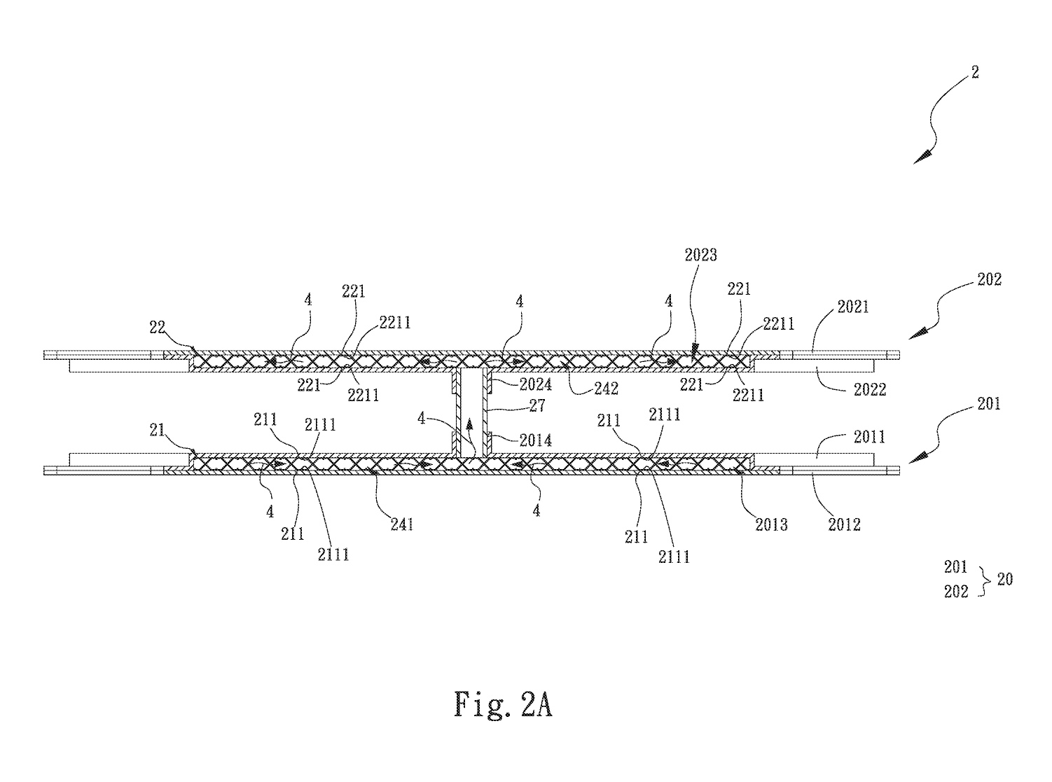

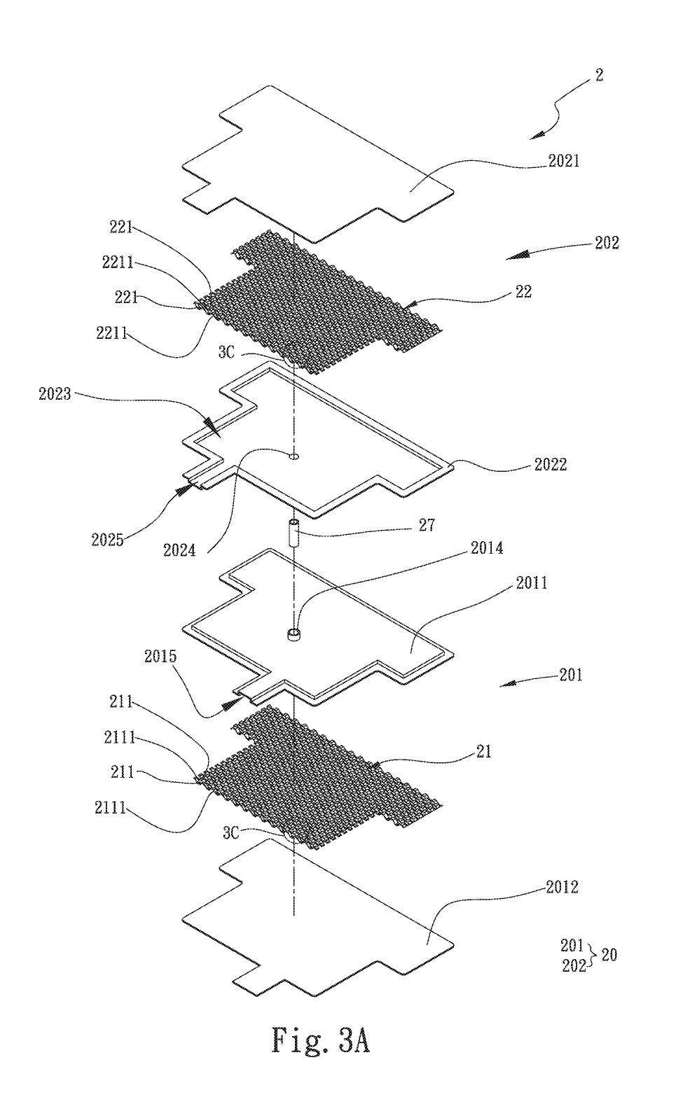

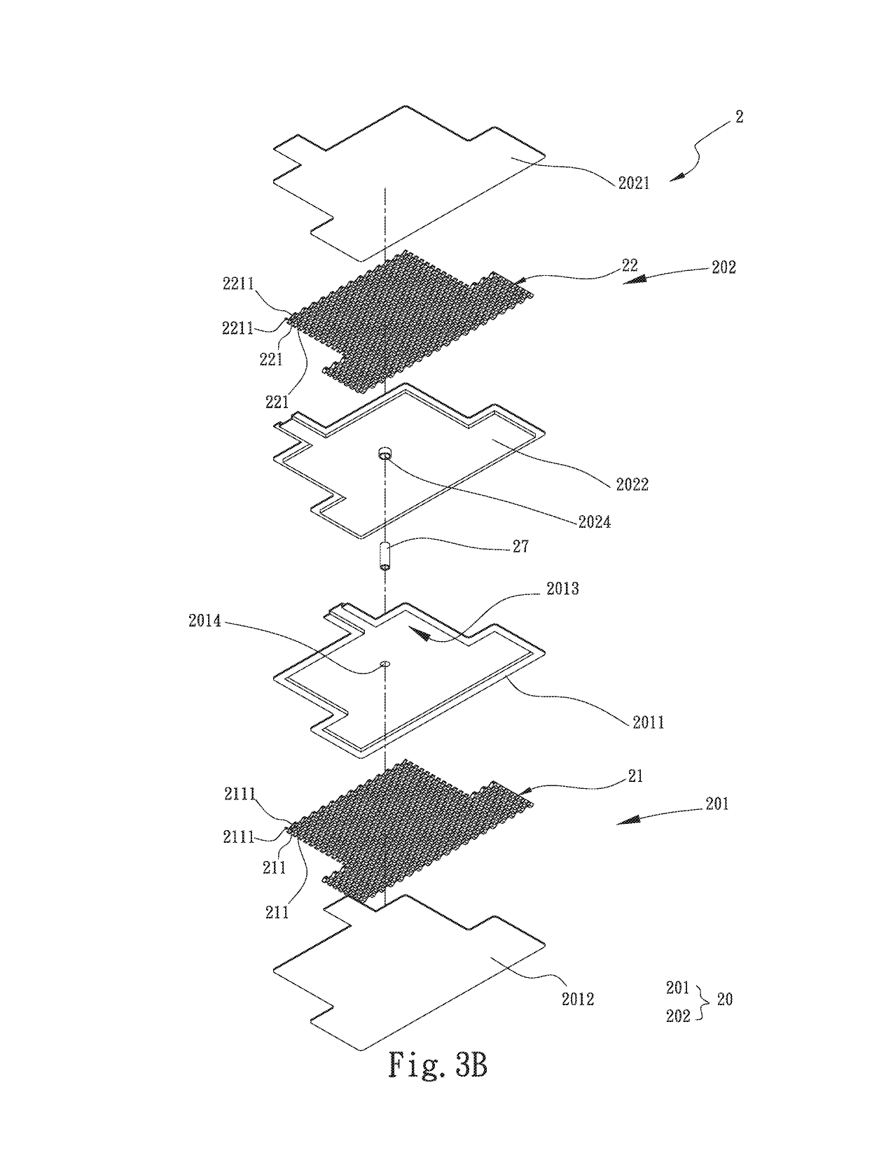

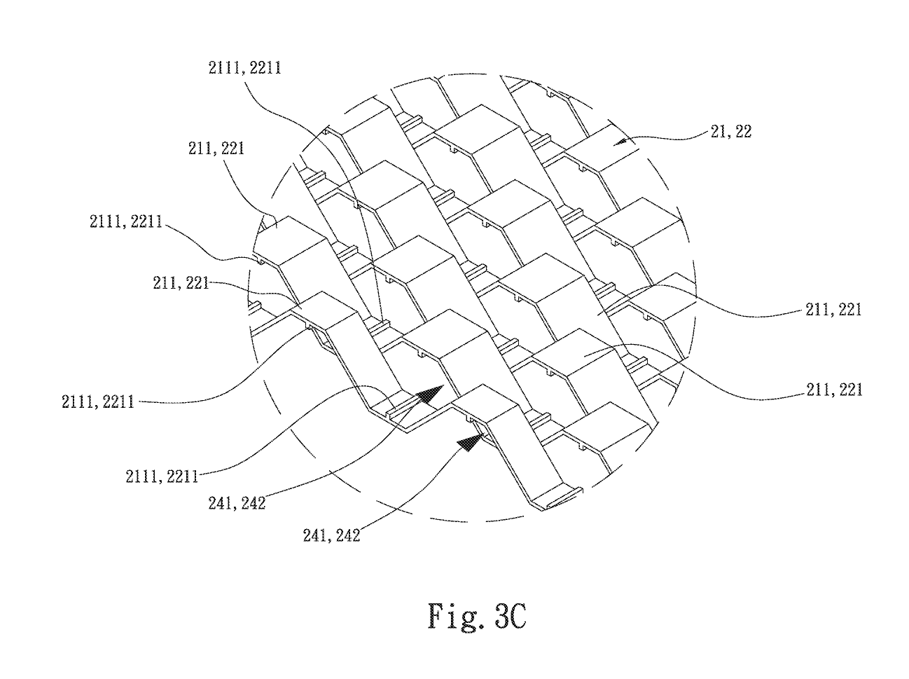

Please refer to FIGS. 2 and 2A, which are assembled perspective and sectional views, respectively, of a water-cooling radiator assembly 2 according to a first embodiment of the present invention; and to FIGS. 3A and 3B, which are exploded top and bottom perspective views, respectively, of the first embodiment of the present invention. As shown, the water-cooling radiator assembly 2 in the first embodiment includes a liquid-receiving plate unit 20, a first flow-disturbing unit 21, and at least one communicating pipe 27. The liquid-receiving plate unit 20 includes a first liquid-receiving plate 201 and a second liquid-receiving plate 202, which can be made of gold, silver, copper, iron, titanium, aluminum or stainless steel, or any alloy of these metal materials. The first liquid-receiving plate 201 includes a first top plate member 2011 and a first bottom plate member 2012 closed and connected to each other, a first liquid chamber 2013 defined between the first top and bottom plate members 2011, 2012, a first opening 2014 penetrating the first top plate member 2011 and communicable with the first liquid chamber 2013, and at least one liquid inlet 2015. In the illustrated first embodiment, there is shown one liquid inlet 2015 formed near one lateral side of the first liquid-receiving plate 201 and communicable with the first liquid chamber 2013. A working liquid 4 flows into the first liquid chamber 2013 via the liquid inlet 2015. In the illustrated embodiment, the working liquid 4 is a ketone liquid. However, the working liquid 4 is not limited to the ketone liquid but can be any other liquid that provides heat dissipation effect, such pure water, inorganic compounds, alcohols, liquid metals, coolants and organic compounds.

The second liquid-receiving plate 202 is disposed above and spaced from the first liquid-receiving plate 201. The second liquid-receiving plate 202 includes a second top plate member 2021 and a second bottom plate member 2022 closed and connected to each other, a second liquid chamber 2023 defined between the second top and bottom plate members 2021, 2022, a second opening 2024 penetrating the second bottom plate member 2022 and communicable with the second liquid chamber 2023, and at least one liquid outlet 2025. In the illustrated first embodiment, there is shown one liquid outlet 2025 formed near one lateral side of the second liquid-receiving plate 202 and communicable with the second liquid chamber 2023. In the illustrated first embodiment, there is shown only one communicating pipe 27, which can be made of gold, silver, copper, iron, aluminum, titanium or stainless steel, or any alloy of these metal materials. The communicating pipe 27 has one end communicably connected to the first opening 2014 formed on the first top plate member 2011 and another end communicably connected to the second opening 2024 formed on the second bottom plate member 2022, so that the communicating pipe 27 communicates the first liquid chamber 2013 with the second liquid chamber 2023 via the first opening 2014 and the second opening 2024. It is understood the number of the liquid-receiving plates included in the liquid-receiving plate unit 20 is not limited two, and the number of the communicating pipes 27 is not limited to one. In practical implementation of the present invention, the number of the liquid-receiving plates can be increased according to actual need in heat dissipation so that three or four or more liquid-receiving plates can be superposed while vertically spaced from one another. Similarly, the number of the communicating pipes provided between two vertically spaced liquid-receiving plates can be increased to be three or six, for example.

The water-cooling radiator assembly 2 can further include a second flow-disturbing unit 22. The first and the second flow-disturbing unit 21, 22 provide the effects of disturbing liquid flows and supporting the first and the second liquid-receiving plate 201, 202, respectively. The first and the second flow-disturbing unit 21, 22 are arranged in the first and the second liquid chamber 2013, 2023, respectively. In the illustrated first embodiment, the first flow-disturbing unit 21 in the first liquid chamber 2013 has an upper side in contact with an inner surface of the first top plate member 2011 and a lower side in contact with an inner surface of the first bottom plate member 2012; and the second flow-disturbing unit 22 in the second liquid chamber 2023 has an upper side in contact with an inner surface of the second top plate member 2021 and a lower side in contact with an inner surface of the second bottom plate member 2022. In an operable embodiment of the present invention, the second flow-disturbing unit 22 can be omitted from the second liquid chamber 2023, so that the water-cooling radiator assembly 2 has only the first flow-disturbing unit 21 arranged in the first liquid chamber 2013. Alternatively, according to another operable embodiment, the first flow-disturbing unit 21 can be omitted from the first liquid chamber 2013 while the second liquid chamber 2023 has the second flow-disturbing unit 22 arranged therein.

FIG. 3C is an enlarged view of the circled area 3C in FIG. 3A. Please refer to FIGS. 2A, 3A and 3B along with FIG. 3C. The first flow-disturbing unit 21 includes a plurality of first flow-disturbing elements 211, which are arranged in rows and lines to together define a plurality of first liquid passages 241 between them. The second flow-disturbing unit 22 includes a plurality of second flow-disturbing elements 221, which are arranged in rows and lines to together define a plurality of second liquid passages 242 between them. In the illustrated first embodiment, the first and second flow-disturbing elements 211, 221 are respectively a wave-shaped plate. However, it is understood the first and second flow-disturbing elements 211, 221 are not necessarily limited to wave-shaped plates. In practical implementation of the present invention, the first and second flow-disturbing elements 211, 221 can be otherwise helical-shaped elements or any other geometric-shaped elements arranged in rows and lines side-by-side. Alternatively, the first and the second flow-disturbing elements 211, 221 in any two adjacent rows can be respectively arranged in a staggered manner. According to the present invention, any structure that can produce a flow disturbing or stirring effect to lower liquid flow speed and increase liquid flow time in the liquid chambers of the water-cooling radiator assembly 2 is included in the scope of the first and the second flow-disturbing unit 21, 22 of the present invention. In the present invention, the first and second flow-disturbing elements 211, 221 can be made of gold, silver, cooper, iron, titanium, aluminum or stainless steel, or any alloy of these metal materials.

Any two adjacent first flow-disturbing elements 211 located in the same row have shapes that are inverted relative to each other. The first flow-disturbing elements 211 are located in the first liquid chamber 2013 to function as an internal structural support to the first liquid-receiving plate 201. The first flow-disturbing elements 211 are respectively formed with a first flow-disturbing means 2111, which is located on one side of each first flow-disturbing element 211 that faces toward the first liquid passages 241. Similarly, any two adjacent second flow-disturbing elements 221 located in the same row have shapes that are inverted relative to each other. The second flow-disturbing elements 221 are located in the second liquid chamber 2023 to function as an internal structural support to the second liquid-receiving plate 202. The second flow-disturbing elements 221 are respectively formed with a second flow-disturbing means 2211, which is located on one side of each second flow-disturbing element 221 that faces toward the second liquid passages 242. In another operable embodiment of the present invention, the first and the second flow-disturbing means 2111, 2211 can be omitted from the first and the second flow-disturbing elements 211, 221, respectively.

When the working liquid 4 flows into the first liquid chamber 2013 via the liquid inlet 2015 of the first liquid-receiving plate 201 and further flows through the first flow-disturbing unit 21 in the first liquid chamber 2013, the working liquid 4 is disturbed and stirred by the first flow-disturbing elements 211, so that streams of the working liquid 4 flowed through different first flow-disturbing elements 211 reach a homogeneous temperature. Also, the working liquid 4 flowing through the first liquid passages 241 will strike against the first flow-disturbing means 2111 to produce eddies, which effectively lowers the flow speed and increases the flow time of the working liquid 4 in the first liquid chamber 2013. At this point, heat carried by the working liquid 4 is directly absorbed by inner surfaces of the first liquid-receiving plate 201 and transferred to an outer side of the first liquid-receiving plate 201, from where the heat is dissipated into ambient air. After flowing through the first liquid passages 241, the working liquid 4 flows into the second liquid chamber 202 via the communicating pipe 27. In the second liquid chamber 2023, the working liquid 4 flows through the second flow-disturbing elements 221 and is disturbed and stirred, so that streams of the working fluid 4 flowed through different second flow-disturbing elements 221 reach a homogeneous temperature. Also, the working liquid 4 flowing through the second liquid passages 242 will strike against the second flow-disturbing means 2211 to produce eddies, which effectively lowers the flow speed and increases the flow time of the working liquid 4 in the second liquid chamber 2023. At this point, heat carried by the working liquid 4 is directly absorbed by inner surfaces of the second liquid-receiving plate 202 and transferred to an outer side of the second liquid-receiving plate 202, from where the heat is dissipated into ambient air. Finally, the cooled working liquid 4 leaves the second liquid-receiving plate 202 via the liquid outlet 2025.

According to the water-cooling radiator assembly 2 with the above-described structural design, the first and the second flow-disturbing unit 21, 22 can lower the flow speed of the working liquid 4 in the first and the second liquid-receiving plate 201, 202 to thereby effectively increase the time for the working liquid 4 to exchange heat with the first and the second liquid-receiving plate 201, 202. Further, while the working liquid 4 is disturbed and stirred by the first and the second flow-disturbing elements 211, 221, heat carried by the working liquid 4 is also absorbed by the first and the second flow-disturbing elements 211, 221 and transferred to the first and the second liquid-receiving plate 201, 202, respectively, from where the heat is dissipated into ambient air. In other words, the first and second flow-disturbing elements 211, 221 also effectively increase the heat transfer areas and largely upgrade the heat dissipation efficiency of the water-cooling radiator assembly 2 of the present invention. Since the first and the second liquid-receiving plate 201, 202 respectively have a quite large inner surface that are in direct contact with the working liquid 4, they can directly absorb the heat carried by the working liquid 4. Further, the first and the second liquid-receiving plate 201, 202 also respectively have a relatively large outer surface that form quite large heat dissipation areas to enable quick dissipation of the absorbed heat into the ambient air, allowing the water-cooling radiator assembly 2 to have good heat removal performance. Moreover, the lengthwise extended communicating pipe 27 can also increase or extend the flow time of the working liquid 4 therein to effectively increase the time for the working liquid 4 to exchange heat with the communicating pipe 27 and helpfully achieve the purpose of quick heat dissipation.

The water-cooling radiator assembly 2 of the present invention can be applied to electronic equipment, industrial equipment, household appliances, transportation equipment, smart equipment and devices, etc. to cool or dissipate heat from the heat-producing electronic elements or heat sources in these equipment, appliances or devices.

In an operable embodiment of the present invention, the first and the second liquid-receiving plate 201, 202 as well as the communicating pipe 27 are made of a titanium material having a purity of 90% to 99%, such as the commercially pure titanium (CP-Ti). The titanium material has high metal strength, low weight and good heat transfer efficiency and is corrosion resistant to enable effectively upgraded heat dissipation effect and reduced overall weight of the water-cooling radiator assembly 2. In the structural design of the present invention that combines at least one liquid-receiving plate unit 20 and at least one communicating pipe 27, the number and positions of the liquid-receiving plates as well as the number and positions of the communicating pipes between any two adjacent liquid-receiving plates can be actively adjusted or arranged in advance according to the internal space available in an electronic device (not shown) that requires water cooling, so that the heat dissipation effect can be adjusted in different manners.

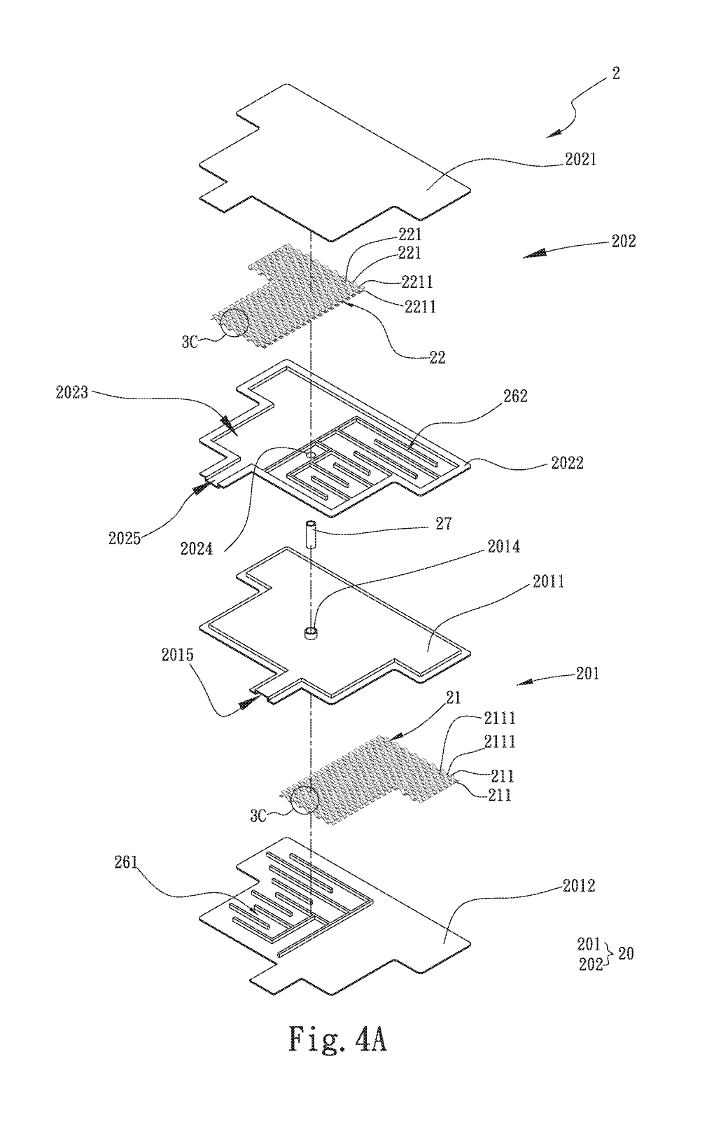

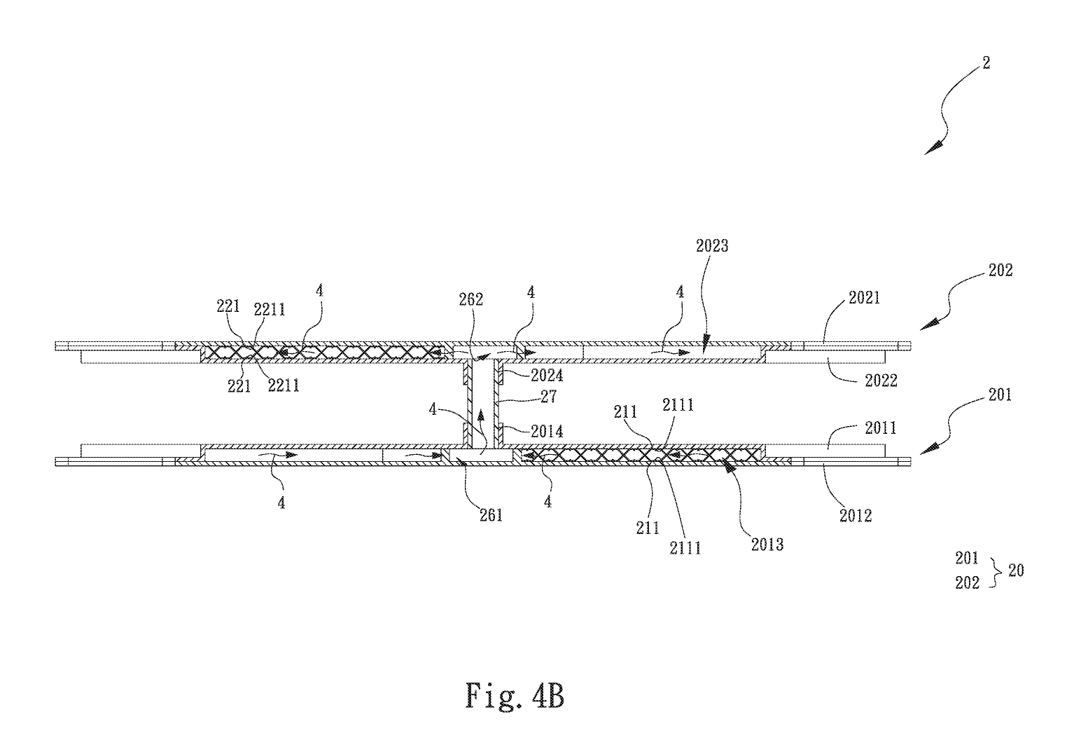

Please refer to FIGS. 4A and 4B that are exploded perspective and assembled sectional views, respectively, of a water-cooling radiator assembly 2 according to a second embodiment of the present invention, and to FIG. 3C again that is also an enlarged view of the circled area 3C in FIG. 4A. As shown, while the second embodiment has first and second liquid-receiving plates 201, 202, first and second flow-disturbing units 21, 22, and at least one communicating pipe 27 that are generally structurally the same as those in the first embodiment, the second embodiment is different from the first one in further having a first flow passage 261 and a second flow passage 262 included in the water-cooling radiator assembly 2. The first flow passage 261 is provided in the first liquid chamber 2013 at a position laterally opposite to the first flow-disturbing unit 21. In the second embodiment shown in FIGS. 4A and 4B, the first flow passage 261 is located at a left zone in the first liquid chamber 2013 while the first flow-disturbing unit 21 is located at a right zone in the first liquid chamber 2013. Similarly, the second flow passage 262 is provided in the second liquid chamber 2023 at a position laterally opposite to the second flow-disturbing unit 22. In the second embodiment shown in FIGS. 4A and 4B, the second flow passage 262 is located at a right zone in the second liquid chamber 2023 while the second flow-disturbing unit 22 is located at a left zone in the second liquid chamber 2023. The first and the second flow passage 261, 262 serve as guide paths for the working liquid 4 in the first and the second liquid-receiving plate 201, 202, respectively. In the illustrated second embodiment, the first flow passage 261 is formed on an inner surface of the first bottom plate member 2012 and winding through the first liquid chamber 2013, and the second flow passage 262 is formed on an inner surface of the second bottom plate member 2022 and winding through the second liquid chamber 2023. It is understood the arrangement of the first flow-disturbing unit 21 and the first flow passage 261 in the first liquid-receiving plate 201 as well as the arrangement of the second flow-disturbing unit 22 and the second flow passage 262 in the second liquid-receiving plate 202 are not necessarily limited to the above-described positions. Any arrangement that disposes the first flow-disturbing unit 21 and the first flow passage 261 in the first liquid chamber 2013 and disposes the second flow-disturbing unit 22 and the second flow passage 262 in the second liquid chamber 2023 shall be included in the spirit and scope of the present invention.

In an operable embodiment of the present invention, the second flow passage 262 can be omitted from the second liquid chamber 2023, so that the entire area, including the left and the right zone, in the second liquid chamber 2023 is occupied only by the second flow-disturbing unit 22.

According to the second embodiment, the working liquid 4 flowing through the first flow-disturbing unit 21 in the first liquid chamber 2013 is disturbed and stirred by the first flow-disturbing elements 211, so that streams of the working liquid 4 flowed through different first flow-disturbing elements 211 reach a homogeneous temperature. Then, the working liquid 4 flowing through the first liquid passages 241 will strike against the first flow-disturbing means 2111 to produce eddies. After passing through the first liquid passages 241, the working liquid 4 flows along the winding first flow passage 261 toward the first opening 2014, and then flows into the second liquid chamber 2023 via the first opening 2014 and the communicating pipe 27. The working liquid 4 in the second liquid chamber 2023 flows along the winding second flow passage 262 toward the second flow-disturbing unit 22 and the liquid outlet 2025. When flowing through the second flow-disturbing unit 22, the working liquid 4 is disturbed and stirred, so that streams of the working liquid 4 flowed through different second flow-disturbing elements 221 reach a homogeneous temperature. Then, the working liquid 4 flowing through the second liquid passages 242 will strike against the second flow-disturbing means 2211 to produce eddies. Finally, the cooled working liquid 4 flowed through the second liquid passages 242 leaves the second liquid chamber 2023 via the liquid outlet 2025. With these arrangements, the water-cooling radiator assembly 2 according to the second embodiment of the present invention can also have good heat removal performance and largely upgraded heat dissipation efficiency.

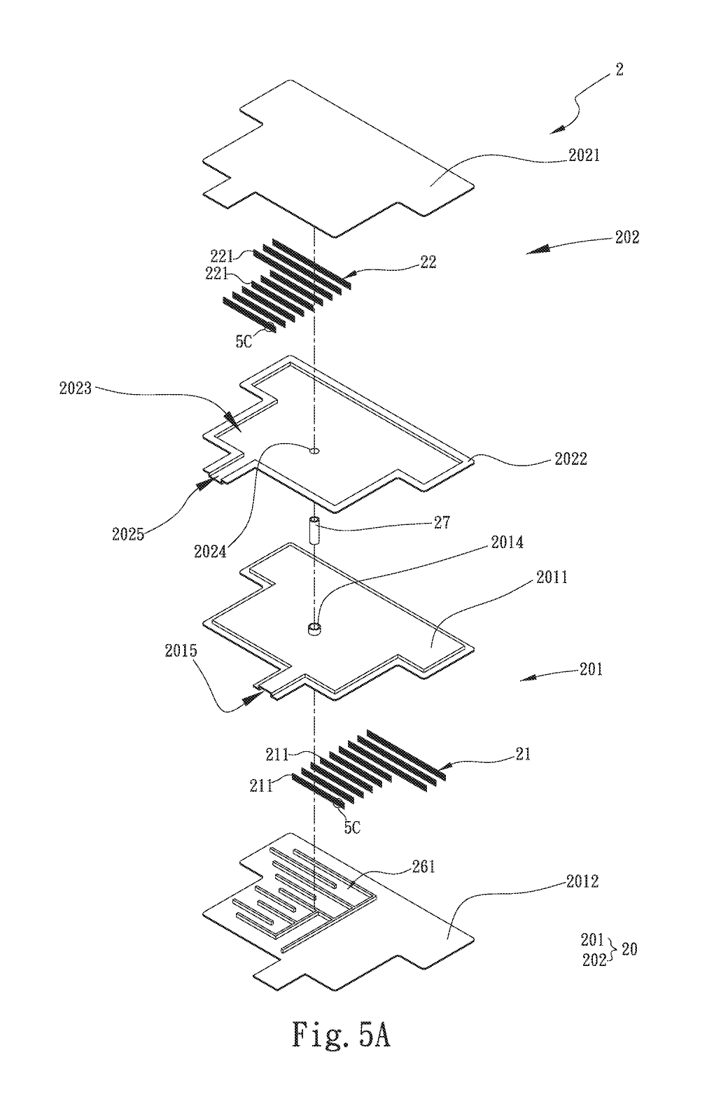

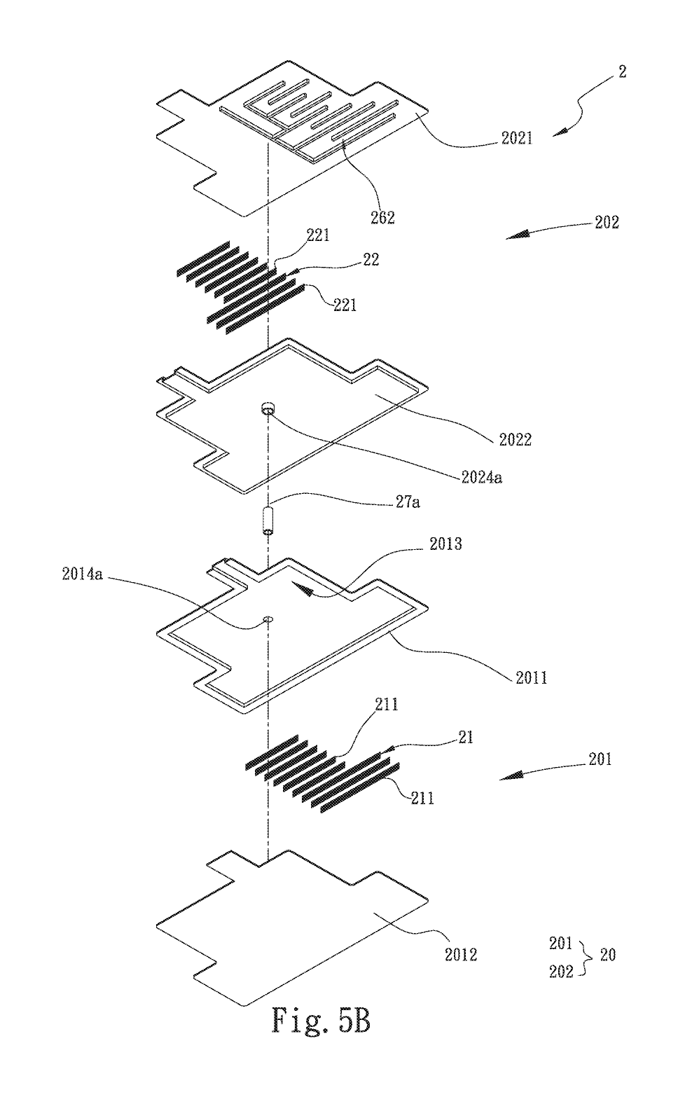

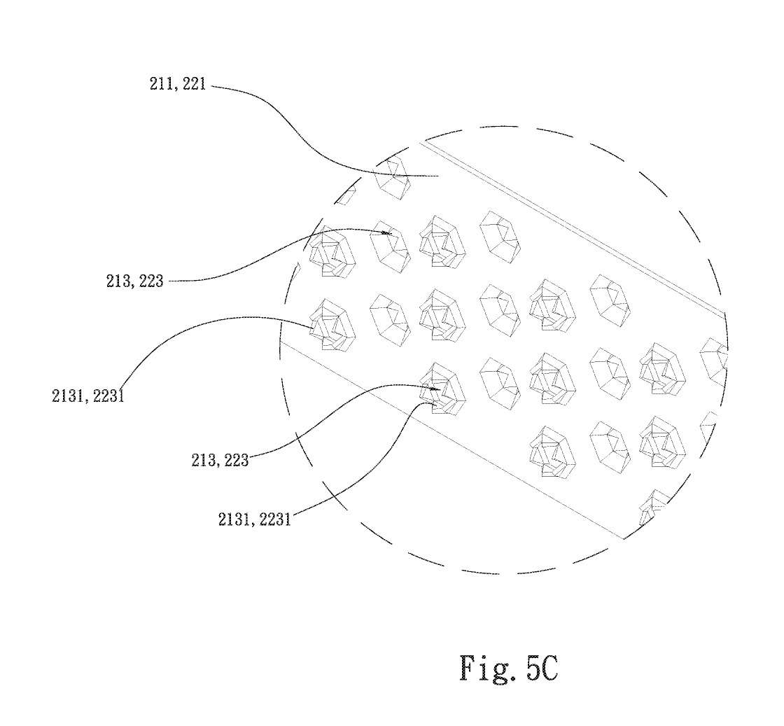

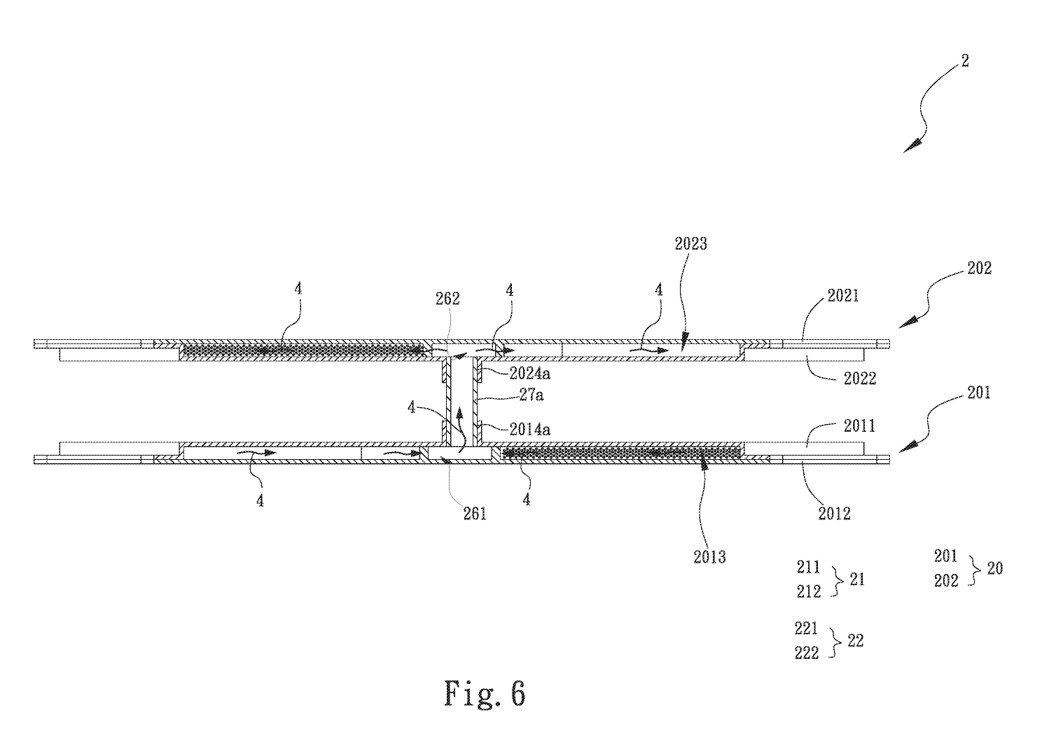

Please refer to FIGS. 5A and 5B that are exploded top and bottom perspective views, respectively, of a water-cooling radiator assembly 2 according to a third embodiment of the present invention; and to FIG. 5C that is an enlarged view of the circled area 5C in FIG. 5A; and also to FIG. 6 that is an assembled sectional view of the third embodiment. As shown, in the third embodiment, the first and the second flow-disturbing elements 211, 221 are respectively in the form of a geometric-shaped strip, such as a rectangular strip, instead of a wave-shaped plate as shown in the first and second embodiments; and the second flow passage 262 is formed on an inner surface of the second top plate member 2021 and winding through the second liquid chamber 2023. According to the third embodiment, the first flow-disturbing elements 211 of the first flow-disturbing unit 21 are arranged in the first liquid chamber 2013 to be equally spaced from one another and located opposite to the first flow passage 261. Similarly, the second flow-disturbing elements 221 of the second flow-disturbing unit 22 are arranged in the second liquid chamber 2023 to be equally spaced from one another and located opposite to the second flow passage 262. In an operable embodiment, the first flow-disturbing elements 211 are unequally spaced from one another in the first liquid chamber 2013 while being located opposite to the first flow passage 261; and the second flow-disturbing elements 221 are also unequally spaced from one another in the second liquid chamber 2023 while being located opposite to the second flow passage 262. As can be clearly seen in FIG. 5C, each of the first flow-disturbing elements 211 is provided with a plurality of first flow-disturbing holes 213, which are so formed that they respectively penetrate the first flow-disturbing element 211 with a first lip portion 2131 formed around each of them and protruded from two opposite side surfaces of the strip-shaped first flow-disturbing element 211. It is noted some of the first flow-disturbing holes 213 have their first lip portions 2131 protruded from one side surface of the strip-shaped first flow-disturbing element 211, while others have their first lop portions 2131 protruded from the opposite side surface of the strip-shaped first flow-disturbing element 211. Similarly, each of the second flow-disturbing elements 221 is provided with a plurality of second flow-disturbing holes 223, which are so formed that they respectively penetrate the second flow-disturbing element 221 with a second lip portion 2231 formed around each of them and protruded from two opposite side surfaces of the strip-shaped second flow-disturbing element 221. It is noted some of the second flow-disturbing holes 223 have their second lip portions 2231 protruded from one side surface of the strip-shaped second flow-disturbing element 221, while others have their second lop portions 2231 protruded from the opposite side surface of the strip-shaped second flow-disturbing element 221. According to the third embodiment, the first and the second flow-disturbing holes 213, 223 can be respectively a hexagonal hole, or any other polygonal hole, such as a triangular, a pentagonal or an octagonal hole, or any other geometric-shaped hole.

In practical implementation of the present invention, two opposite side surfaces of each of the first and the second flow-disturbing elements 211, 221 are machined, for example, using a stamping mold to form the first and the second flow-disturbing holes 213, 223, respectively. When the first and the second flow-disturbing elements 211, 221 are stamped from a first side surface thereof to form the first and the second flow-disturbing holes 213, 223, respectively, the first and the second lip portion 2131, 2231 will be formed on and protruded from an opposite second side surface of the first and the second flow-disturbing elements 211, 221 around the so formed flow-disturbing holes 213, 223. On the other hand, when the first and the second flow-disturbing elements 211, 221 are stamped from the second side surface thereof to form the first and the second flow-disturbing holes 213, 223, respectively, the first and the second lip portion 2131, 2231 will be formed on and protruded from the first side surface of the first and the second flow-disturbing elements 211, 221 around the so formed flow-disturbing holes 213, 223. When the working liquid 4 flows through the first and the second flow-disturbing holes 213, 223, it strikes against the first and the second lip portions 2131, 2231, respectively, and is disturbed and stirred to slow down accordingly. Therefore, the provision of the first and the second flow-disturbing elements 211, 221 having the first and the second flow-disturbing holes 213, 223 and the first and the second lip portions 2131, 2231 formed thereon can effectively lower the flow speed and increase the flow time of the working liquid 4 in the first and the second liquid chamber 2013, 2023 to enable largely upgraded heat dissipation efficiency of the water-cooling radiator assembly 2.

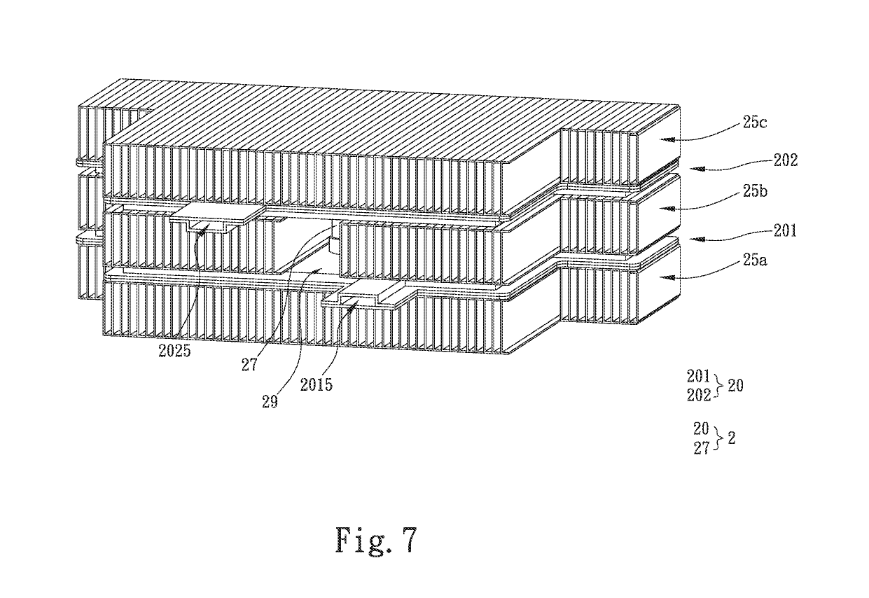

FIG. 7 is an assembled perspective view of a water-cooling radiator assembly 2 according to a fourth embodiment of the present invention. The fourth embodiment is different from the first one in further including a first, a second and a third radiating fin assembly 25a, 25b, 25c, each of which consists of a plurality of radiating fins. The first radiating fin assembly 25a is disposed on a bottom outer side of the first liquid-receiving plate 201; the second radiating fin assembly 25b is disposed in a heat dissipation space 29 defined between the first and the second liquid-receiving plate 201, 202; and the third radiating fin assembly 25c is disposed on a top outer side of the second liquid-receiving plate 202. Heat carried by the working liquid 4 and transferred to the first and the second liquid-receiving plate 201, 202 is more quickly dissipated from the first, the second and the third radiating fin assembly 25a, 25b, 25c into ambient air because the first, second and third radiating fin assemblies 25a, 25b, 25c effectively provide increased heat dissipation areas and accordingly enable good heat removal efficiency.

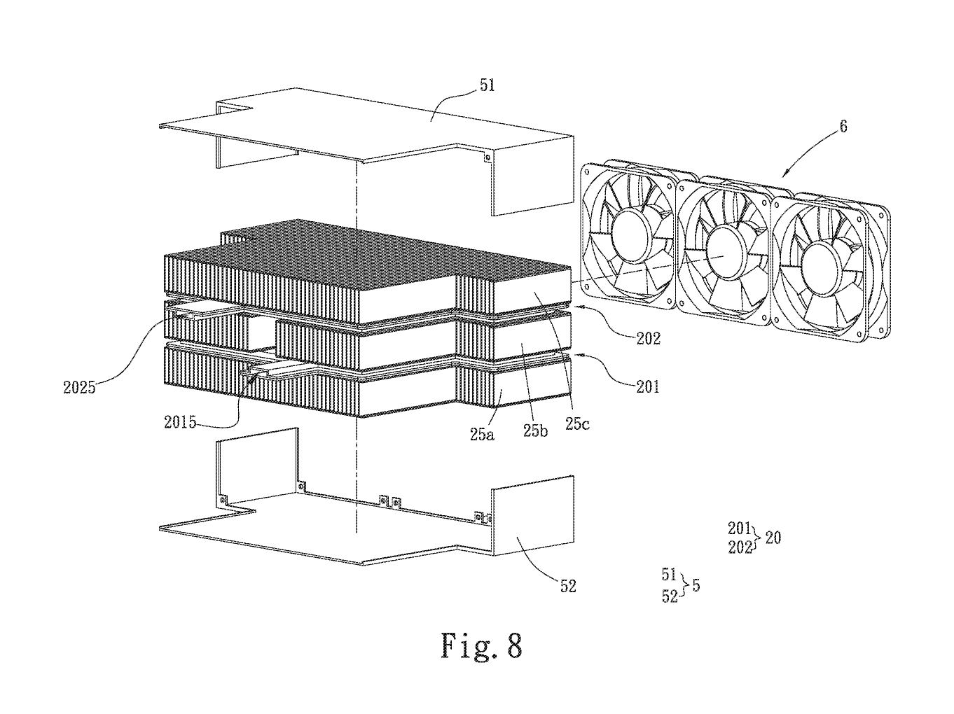

FIG. 8 shows a fifth embodiment of the present invention, which is different from the fourth one in further including a protection unit 5 and a cooling fan bank 6. The protection cover unit 5 includes an upper protection cover 51 and a lower protection cover 52, which are covered onto an outer side of the first and the third radiating fin assembly 25a, 25c, respectively, to protect the first, second and third radiating fin assemblies 25a, 25b, 25c against damages. The cooling fan bank 6 is connected to a lateral open side of the protection cover unit 5 to enable forced heat dissipation from the first, second and third radiating fin assemblies 25a, 25b, 25c, so as to quickly remove heat from the first, second and third radiating fin assemblies 25a, 25b, 25c.

In an operable embodiment, the protection cover unit 5 and the cooling fan bank 6 can be optionally omitted. In another operable embodiment, the protection cover unit 5 can be provided with a fastening unit (not shown) to firmly secure the water-cooling radiator assembly 2 to a carrier, such as a chassis or a motherboard.

In practical implementation of the present invention, the liquid outlet 2025 on the second liquid-receiving plate 202 is correspondingly connected to an end of a pump (not shown), and a cooling module (not shown) in contact with a heat source, such as a CPU or other heat-producing electronic element, can be correspondingly connected to another end of the pump and communicable with the liquid inlet 2015 on the first liquid-receiving plate 201, so that the water-cooling radiator assembly 2, the pump and the cooling module together constitute a water-cooling system. The pump drives or stirs the working liquid 4 to repeatedly circulate between the cooling module and the liquid-receiving plate unit 20 to effectively enable good heat removal performance and quick heat dissipation through heat exchange.

The present invention has been described with some preferred embodiments thereof and it is understood that many changes and modifications in the described embodiments can be carried out without departing from the scope and the spirit of the invention that is intended to be limited only by the appended claims.

What is claimed is:

1. A water-cooling radiator assembly, comprising:
a liquid-receiving plate unit including:
a first liquid-receiving plate internally defining a first liquid chamber and having at least one liquid inlet provided thereon; the first liquid chamber being communicable with the at least one liquid inlet, and a working liquid flowing into the first liquid chamber via the at least one liquid inlet; and
a second liquid-receiving plate internally defining a second liquid chamber and having at least one liquid outlet provided thereon; and the second liquid chamber being communicable with the at least one liquid outlet;
at least one communicating pipe communicably connected to between the first and the second liquid chamber; and
a first flow-disturbing unit being selectively arranged in one of the first and the second liquid chamber.

2. The water-cooling radiator assembly as claimed in claim 1, wherein the first liquid-receiving plate includes a first top plate member and a first bottom plate member, which are closed and connected to each other to define the first liquid chamber in between them; and the first flow-disturbing unit being arranged in the first liquid chamber with an upper side in contact with an inner surface of the first top plate member and a lower side in contact with an inner surface of the first bottom plate member.

3. The water-cooling radiator assembly as claimed in claim 2, further comprising a second flow-disturbing unit; and wherein the second liquid-receiving plate includes a second top plate member and a second bottom plate member, which are closed and connected to each other to define the second liquid chamber in between them; and the second flow-disturbing unit being arranged in the second liquid chamber with an upper side in contact with an inner surface of the second top plate member and a lower side in contact with an inner surface of the second bottom plate member.

4. The water-cooling radiator assembly as claimed in claim 3, wherein the first flow-disturbing unit includes a plurality of first flow-disturbing elements arranged in rows and lines to together define a plurality of first liquid passages between them; and each of the first flow-disturbing elements being formed with a first flow-disturbing means, which is located on one side of the first flow-disturbing element that faces toward the first liquid passages.

5. The water-cooling radiator assembly as claimed in claim 4, wherein the second flow-disturbing unit includes a plurality of second flow-disturbing elements arranged in rows and lines to together define a plurality of second liquid passages between them; and each of the second flow-disturbing elements being formed with a second flow-disturbing means, which is located on one side of the second flow-disturbing element that faces toward the second liquid passages.

6. The water-cooling radiator assembly as claimed in claim 5, wherein the first and the second flow-disturbing elements are respectively a wave-shaped plate; any two adjacent first flow-disturbing elements in the same row have shapes that are inverted relative to each other; and any two adjacent second flow-disturbing elements in the same row have shapes that are inverted relative to each other.

7. The water-cooling radiator assembly as claimed in claim 3, wherein the first flow-disturbing unit includes a plurality of first flow-disturbing elements, which are arranged in the first liquid chamber to be selectively equally or unequally spaced from one another, and each of the first flow-disturbing elements being provided with a plurality of first flow-disturbing holes, which respectively penetrate the first flow-disturbing element.

8. The water-cooling radiator assembly as claimed in claim 7, wherein the second flow-disturbing unit includes a plurality of second flow-disturbing elements, which are arranged in the second liquid chamber to be selectively equally or unequally spaced from one another, and each of the second flow-disturbing elements being provided with a plurality of second flow-disturbing holes, which respectively penetrate the second flow-disturbing element.

9. The water-cooling radiator assembly as claimed in claim 8, wherein the first and the second flow-disturbing holes respectively have a shape selected from the group consisting of a hexagonal hole, any polygonal hole and any geometric-shaped hole.

10. The water-cooling radiator assembly as claimed in claim 3, further comprising a first flow passage provided in the first liquid chamber at a position laterally opposite to the first flow-disturbing unit arranged in the first liquid chamber.

11. The water-cooling radiator assembly as claimed in claim 10, further comprising a second flow passage provided in the second liquid chamber at a position laterally opposite to the second flow-disturbing unit arranged in the second liquid chamber.

12. The water-cooling radiator assembly as claimed in claim 3, wherein the first liquid-receiving plate includes at least one first opening penetrating the first top plate member; and the at least one communicating pipe being correspondingly communicably connected at an end to the at least one first opening to communicate with the first liquid chamber via the at least one first opening.

13. The water-cooling radiator assembly as claimed in claim 12, wherein the second liquid-receiving plate includes at least one second opening penetrating the second bottom plate member; and the at least one communicating pipe being correspondingly communicably connected at another end to the at least one second opening to communicate with the second liquid chamber via the at least one second opening.

14. The water-cooling radiator assembly as claimed in claim 1, further comprising a first and a second radiating fin assembly, and wherein the first liquid-receiving plate is disposed below and spaced from the second liquid-receiving plate; the first radiating fin assembly being disposed on a bottom outer side of the first liquid-receiving plate, and the second radiating fin assembly being disposed between the first and the second liquid-receiving plate.

15. The water-cooling radiator assembly as claimed in claim 14, further comprising a third radiating fin assembly disposed on a top outer side of the second liquid-receiving plate, a protection cover unit covered onto an outer side of the first and the third radiating fin assembly, and a cooling fan bank connected to a lateral open side of the protection cover unit.

16. The water-cooling radiator assembly as claimed in claim 1, wherein the first and the second liquid-receiving plate as well as the at least one communicating pipe are made of a material selected from the group consisting of gold, silver, cooper, iron, titanium, aluminum and stainless steel and any alloy thereof.

17. The water-cooling radiator assembly as claimed in claim 8, wherein a part of the first flow-disturbing holes provided on each of the first flow-disturbing elements respectively have a first lip portion formed therearound and protruded from one of two opposite side surfaces of the first flow-disturbing element, while other first flow-disturbing holes provided on each of the first flow-disturbing elements respectively have a first lip portion formed therearound and protruded from the other side surface of the first flow-disturbing element; and wherein a part of the second flow-disturbing holes provided on each of the second flow-disturbing elements respectively have a second lip portion formed therearound and protruded from one of two opposite side surfaces of the second flow-disturbing element, while other second flow-disturbing holes provided on each of the second flow-disturbing elements respectively have a second lip portion formed therearound and protruded from the other side surface of the second flow-disturbing element.
